(19) United States
(12) Patent Application Publication
(10) Pub. No.: US 2013/0196572 A1
(43) Pub. Date: Aug. 1, 2013

(54) CONDITIONING A PAD IN A CLEANING MODULE

(71) Applicants: Sen-Hou Ko, Sunnyvale, CA (US); Hui Chen, Burlingame, CA (US)

(72) Inventors: Sen-Hou Ko, Sunnyvale, CA (US); Hui Chen, Burlingame, CA (US)

(21) Appl. No.: 13/360,353

(22) Filed: Jan. 27, 2012

(51) Int. Cl. H01L 21/304; B24B 37/04; B24B 53/017; B24B 49/00

(52) U.S. Cl. 451/11; 451/111; 451/1

(57) ABSTRACT

A particle cleaning module includes a housing, a substrate holder, a pad holder, an actuator and a pad conditioner. The substrate holder is disposed in the housing, is configured to retain a substrate in a substantially vertical orientation, and is rotatable on a first axis. The pad holder is disposed in the housing, has a pad retaining surface facing the substrate holder in a parallel and spaced apart relation, and is rotatable on a second axis parallel to the first axis. The actuator is operable to move the pad holder relative to the substrate holder to change a distance defined between the pad retaining surface and the substrate. The pad conditioner is disposed in the housing and has a conditioning surface oriented parallel to the pad retaining surface.

### TECHNICAL FIELD

A method and apparatus for cleaning and/or polishing a substrate after chemical mechanical planarizing (CMP).

### BACKGROUND

In the process of fabricating modern semiconductor integrated circuits (ICs), it is often necessary to planarize surfaces prior to depositing subsequent, e.g., to achieve tolerances for photolithography or to remove an overlying layer. One method for planarizing a layer during IC fabrication is chemical mechanical planarizing (CMP). In general, CMP involves the relative movement of the substrate held in a polishing head against a polishing material to remove surface irregularities from the substrate. In a CMP process, the polishing material is wetted with a polishing fluid that may contain at least one of an abrasive or chemical polishing composition. This process may be electrically assisted to electrochemically planarize conductive material on the substrate.

Planarizing hard materials such as oxides typically requires that the polishing fluid or the polishing material itself include abrasives. As the abrasives often cling or are become partially embedded in the layer of material being polished, the substrate is processed on a buffing module to remove the abrasives from the polished layer. The buffing module removes the abrasives and polishing fluid used during the CMP process by moving the substrate which is still retained in the polishing head against a buffing material in the presence of deionized water or chemical solutions. The buffing module is substantially identical to the CMP module except for the polishing fluids utilized and the material on which the substrate is processed.

Once buffed, the substrate is transferred to a series of cleaning modules that further remove any remaining abrasive particles and/or other contaminants that cling to the substrate after the planarizing and buffing process before they can harden on the substrate and create defects. The cleaning modules may include, for example, a megasonic cleaner, a scrubber or scrubbers, and a dryer. The cleaning modules that support the substrates in a vertical orientation are especially advantageous, as they also utilize gravity to enhance removal of particles during the cleaning process, and are also typically more compact.

One type of cleaning module includes cylindrical rollers that are brought into contact with a surface of a substrate to remove the abrasive particles and/or other contaminants. For example, a cylindrical roller having a brush body disposed thereon can be caused to rotate and urged against a rotating substrate to clean the substrate after a CMP process. Alternatively, the cleaning module can function as a buffing module. For example, a cylindrical roller having a soft pad material disposed thereon can be caused to rotate and urged against a rotating substrate to buff the substrate.

### SUMMARY

As noted above, polishing processes tend to leave abrasives and/or contaminants (collectively debris) on the surface of the substrate. The cleaning or buffing process tends to transfer this debris onto the brush body or pad material being used for cleaning or buffing. To avoid accumulation of the debris, or to maintain the brush body or pad material in a consistent state of roughness from substrate-to-substrate, the brush body or pad material can be conditioned, e.g., abraded with a harder body. However, the conditioning process tends to wear away the brush body or pad material.

A proposed cleaning or buffing module holds the substrate in a vertical orientation while a disk-shaped brush or pad is brought into contact with the substrate. In the case of a cleaning or buffing module that uses a roller, a conditioning bar can located on the side of the roller opposite the space where the substrate will be located. However, such a configuration is inappropriate for a disk-shaped brush or pad because of the conditioner needs to be located to contact the face of the disk that contacts the substrate. To address this issue, the conditioner can be located in the substrate holder or to the side of the substrate holder in a position reachable by the disk-shaped brush or pad.

Because the substrate is held in a vertical orientation, gravity does not cause the substrate to rest on the brush or pad. Rather, contact between the substrate and the brush or pad is controlled by an actuator that controls the horizontal position of a support for the brush or pad. As the brush or pad wears, the compression of the brush or pad against the substrate can vary from substrate-to-substrate, resulting in variations in effectiveness of cleaning or buffing from substrate-to-substrate. To address this issue, a load cell can be installed in the module. The brush or pad can be brought into contact with the load cell and the applied pressure measured as a function of position of the support. This permits a controller to adjust the horizontal position of the support to achieve consistent compression from substrate-to-substrate.

In one aspect a particle cleaning module includes a housing, a substrate holder disposed in the housing, a pad holder disposed in the housing, an actuator and a pad conditioner disposed in the housing. The substrate holder is configured to retain a substrate in a substantially vertical orientation and is rotatable on a first axis. The pad holder has a pad retaining surface facing the substrate holder in a parallel and spaced apart relation, and the pad holder is rotatable on a second axis parallel to the first axis. The actuator is operable to move the pad holder relative to the substrate holder to change a distance defined between the pad retaining surface and the substrate. The pad conditioner has a conditioning surface oriented parallel to the pad retaining surface.

Implementations may include one or more of the following features. The substrate holder may be configured to hold the substrate in a plane, and the conditioning surface may be positioned on a side of the plane further from the pad holder. The pad conditioner may be mounted on and rotate with the substrate holder. The first axis of rotation may pass approximately through a center of the pad conditioner. The conditioning surface may be recessed relative to a substrate mounting surface of the substrate holder. The actuator may be operable to move the pad support along a direction parallel to the second axis. The actuator may be operable to move the pad support laterally along a direction perpendicular to the second axis to a position laterally separated from the substrate holder, and the pad conditioner may be located at the position laterally separated from the substrate holder. The pad may formed of polyurethane and the pad conditioner may include abrasive diamond particles. The pad may be formed of polyvinyl alcohol and the pad conditioner may be glass. There may be passages through the pad conditioner, and a cleaning liquid supply may inject the cleaning liquid through the passages.

In another aspect, a particle cleaning module includes a housing, a substrate holder disposed in the housing, a pad holder disposed in the housing, an actuator, a pad conditioner disposed in the housing, and a pressure sensor. The substrate holder is configured to retain a substrate in a substantially vertical orientation in a first plane. The pad holder has a pad retaining surface and is configured to retain a pad in a substantially vertical orientation in a second plane parallel to the first plane. The actuator is operable to move the pad holder relative to the substrate holder along a direction normal to the first plane to change a distance between the first plane and the second plane. The actuator is configured to generate or receive a first signal representing a horizontal position of the substrate holder along the direction. The pad conditioner has a conditioning surface oriented parallel to the pad retaining surface. The pressure sensor having a contact surface and is configured to generate a second signal representing a load on the contact surface.

Implementations may include one or more of the following features. A controller may be configured to receive the first signal and the second signal. The controller may be configured to cause the actuator to adjust a horizontal position of the substrate holder based on the first signal and the second signal. The controller may be configured to measure a position Z1 of the substrate holder for a pressure P1 prior to processing of a first substrate, and may be configured to determine a position Z3 of the substrate holder to achieve the pressure P1 after processing of the first substrate. The controller may be configured to position the substrate holder at a position Z2 during processing of the first substrate, and may be configured to position the substrate holder at a position Z4=Z2+ΔZ for polishing of a subsequent second substrate, where ΔZ=Z3−Z1. The contact surface may include the conditioning surface. The pad conditioner may be mounted on the substrate holder. The pressure sensor may include a load cell positioned between the pad conditioner and a motor to rotate a drive shaft secured to the substrate holder. The contact surface may include the pad retaining surface. The substrate holder may be rotatable about a first axis and the pad holder may be rotatable about a second axis parallel to the first axis.

Implementations may include one or more of the following advantages. A conditioner may be provided to condition a disk-shaped brush or pad in a module that holds a substrate in a vertical orientation. By incorporating the conditioner into the substrate hold, a conditioner may be provided without requiring additional space. The brush or pad may be brought into contact with the load cell, and the applied pressure may be measured. A controller may adjust the horizontal position of the support to achieve consistent compression from substrate-to-substrate, which may improve cleaning or buffing uniformity.

### BRIEF DESCRIPTION OF THE DRAWINGS

So that the manner in which the above recited embodiments of the invention are obtained and can be understood in detail, a more particular description, briefly summarized above, may be had by reference to the embodiments thereof, which are illustrated in the appended drawings. It is to be noted, however, that the appended drawings illustrate only a typical embodiment, and there may be other equally effective embodiments.

FIG. 1 illustrates a top view of a semiconductor substrate chemical mechanical planarization system having a cleaning system which includes one embodiment of a particle cleaning module;

FIG. 2 is a front view of cleaning system depicted in FIG. 1;

FIG. 3 is a cross-sectional view of the particle cleaning module depicted in FIG. 1;

FIG. 4 is a cross-sectional view of the particle cleaning module taken along the section line 4-4 of FIG. 3;

FIG. 5 is a cross-sectional view of the particle cleaning module taken along the section line 5-5 of FIG. 3;

FIG. 6 is a side view of a pad holder engaging a pad with a substrate retained by the substrate holder within the particle cleaning module of FIG. 1;

FIG. 7 is a cross-sectional view of the particle cleaning module depicted in FIG. 3 in which the pad is moved into contact with a conditioner;

FIG. 8 is a side view of a pad holder engaging a pad with a conditioner in the substrate holder within the particle cleaning module of FIG. 1.

FIGS. 9A and 9B are front views of a pad conditioner from the particle cleaning module of FIG. 1; and

FIGS. 10A and 10B are cross-sectional views of other implementations of a particle cleaning module that includes a pressure sensor.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

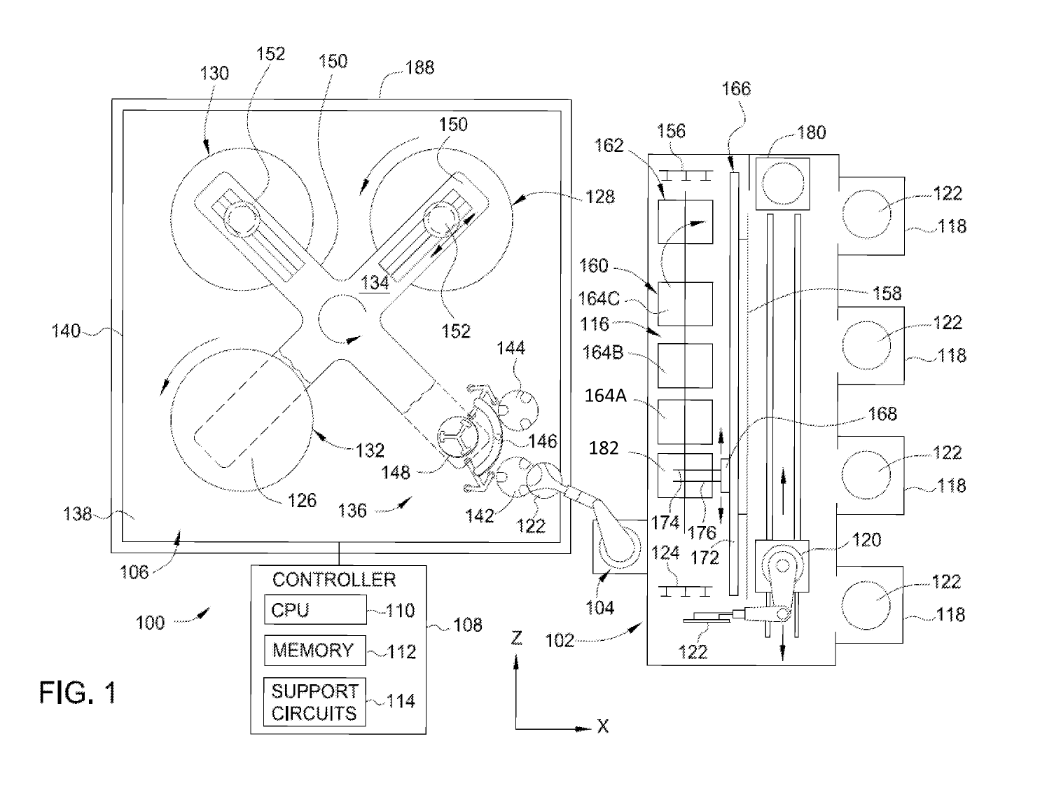

FIG. 1 illustrates a top view of a semiconductor substrate chemical mechanical planarization (CMP) system 100 having a cleaning system 116 that includes a particle cleaning module 182. Although the exemplary configurations are provided for the CMP system 100 and cleaning system 116 in FIG. 1, it is contemplated that embodiments of the particle cleaning module 182 may be utilized alone, or with cleaning systems having alternative configurations and/or CMP systems having alternative configurations.

In addition to the cleaning system 116, the exemplary CMP system 100 generally includes a factory interface 102, a loading robot 104, and a planarizing module 106. The loading robot 104 is disposed proximate the factory interface 102 and the planarizing module 106 to facilitate the transfer of substrates 122 therebetween.

A controller 108 is provided to facilitate control and integration of the modules of the CMP system 100. The controller 108 comprises a central processing unit (CPU) 110, a memory 112 and support circuits 114. The controller 108 is coupled to the various components of the CMP system 100 to facilitate control of, for example, the planarizing cleaning and transfer processes.

The factory interface 102 generally includes an interface robot 120 and one or more substrate cassettes 118. The interface robot 120 is employed to transfer substrates 122 between the substrate cassettes 118, the cleaning system 116 and an input module 124. The input module 124 is positioned to facilitate transfer of substrates 122 between the planarizing module 106 and the factory interface 102 as will be further described below.

Optionally, polished substrates exiting the cleaning system 116 may be tested in a metrology system 180 disposed in the factory interface 102. The metrology system 180 may include an optical measuring device, such as the NovaScan 420, available from Nova Measuring Instruments, Inc. located in Sunnyvale, Calif. The metrology system 180 may include a buffer station (not shown) for facilitating entry and egress of substrates from the optical measuring device or other metrology device. One such suitable buffer is described in U.S. Pat. No. 6,244,931, issued Jun. 12, 2001 to Pinson, et al., which is hereby incorporated by reference in its entirety.

The planarizing module 106 includes at least one CMP station. In the embodiment depicted in FIG. 1, the planarizing module 106 includes a plurality of CMP stations, illustrated as a first station 128, a second station 130 and a third station 132 disposed in an environmentally controlled enclosure 188. The polishing stations are configured to perform an oxide or metal planarization process, e.g., utilizing an abrasive containing polishing fluid. It is contemplated that CMP processes to planarized other materials may be alternatively performed, including the use of other types of polishing fluids. As the CMP process is conventional in nature, further description thereof has been omitted for the sake of brevity.

The exemplary planarizing module 106 also includes a transfer station 136 and a carousel 134 that are disposed on an upper or first side 138 of a machine base 140. In one embodiment, the transfer station 136 includes an input buffer station 142, an output buffer station 144, a transfer robot 146 and a load cup assembly 148. The loading robot 104 is configured to retrieve substrates from the input module 124 and transfer the substrates to the input buffer station 142. The loading robot 104 is also utilized to return polished substrates from the output buffer station 144 to the input module 124, from where the polished substrates are then advanced through the cleaning system 116 prior to being returned to the cassettes 118 coupled to the factory interface 102 by the interface robot 120. The transfer robot 146 is utilized to move substrates between the buffer stations 142, 144 and the load cup assembly 148.

In one embodiment, the transfer robot 146 includes two gripper assemblies, each having pneumatic gripper fingers that hold the substrate by the substrate's edge. The transfer robot 146 may simultaneously transfer a substrate to be processed from the input buffer station 142 to the load cup assembly 148 while transferring a processed substrate from the load cup assembly 148 to the output buffer station 144. An example of a transfer station that may be used to advantage is described in U.S. Pat. No. 6,156,124, issued Dec. 5, 2000 to Tobin, which is herein incorporated by reference in its entirety.

The carousel 134 is centrally disposed on the base 140. The carousel 134 typically includes a plurality of arms 150, each supporting a polishing head 152. Two of the arms 150 depicted in FIG. 1 are shown in phantom such that a planarizing surface of a polishing pad 126 of the first station 128 and the transfer station 136 may be seen. The carousel 134 is indexable such that the polishing head assemblies 152 may be moved between the planarizing stations 128, 130, 132 and the transfer station 136. One carousel that may be utilized to advantage is described in U.S. Pat. No. 5,804,507, issued Sep. 8, 1998 to Perlov, et al., which is hereby incorporated by reference in its entirety.

The cleaning system 116 removes polishing debris, abrasives and/or polishing fluid from the polished substrates that remains after polishing. The cleaning system 116 includes a plurality of cleaning modules 160, a substrate handler 166, a dryer 162 and an output module 156. The substrate handler 166 retrieves a processed substrate 122 returning from the planarizing module 106 from the input module 124 and transfers the substrate 122 through the plurality of cleaning modules 160 and dryer 162. The dryer 162 dries substrates exiting the cleaning system 116 and facilitates substrate transfer between the cleaning system 116 and the factory interface 102 by the interface robot 120. The dryer 162 may be a spin-rinse-dryer or other suitable dryer. One example of a suitable dryer 162 may be found as part of the MESA™ or Desica® Substrate Cleaners, both available from Applied Materials, Inc., of Santa Clara, Calif.

In the embodiment depicted in FIG. 1, the cleaning modules 160 utilized in the cleaning system 116 include a megasonic clearing module 164A, the particle cleaning module 182, a first brush module 164B and a second brush module 164C. The first brush module 164B and the second brush module 164C can use cylindrical roller brushes. However, it is to be appreciated that the particle cleaning module 182 of the present invention may be used with cleaning systems incorporating one or more modules having one or more types of modules. For example, the megasonic cleaning module 164A could be omitted, so that the particle cleaning module 182 is the first module and the substrate is carried in sequence from the particle cleaning module 182, to the first brush module 164B and then to the second brush module 164C. Although the particle cleaning module 182 need not be the first module in the sequence, inclusion of the conditioner device in the first brush module in the sequence is advantageous in order to reduce contamination of the brushes in subsequent brush modules in the sequence.

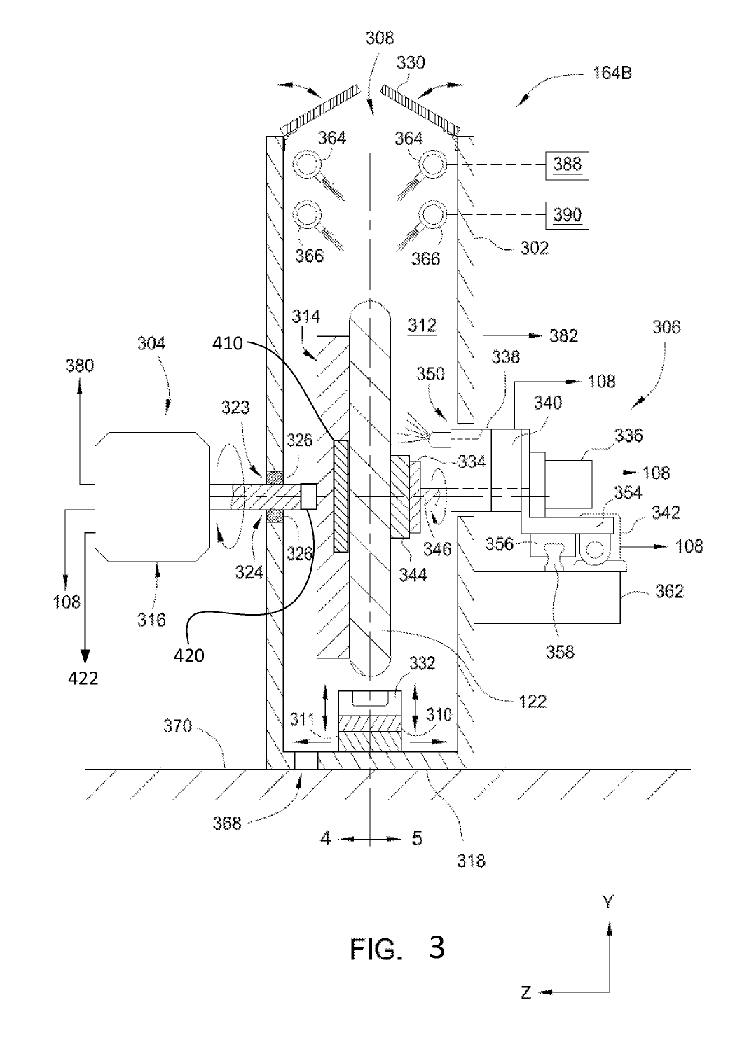

Each of the modules 160 is configured to process a vertically oriented substrate, i.e., one in which the polished surface is in a substantially vertical plane. The vertical plane is represented by the Y-axis, which is perpendicular to the X-axis and Z-axis shown in FIG. 1. The particle cleaning module 182 will be discussed in detail further below with reference to FIG. 3.

In operation, the CMP system 100 is initiated with the substrate 122 being transferred from one of the cassettes 118 to the input module 124 by the interface robot 120. The loading robot 104 then moves the substrate from the input module 124 to the transfer station 136 of the planarizing module 106. The substrate 122 is loaded into the polishing head 152 moved over and polished against the polishing pad 126 while in a horizontal orientation. Once the substrate is polished, polishing substrates 122 are returned to the transfer station 136 from where the robot 104 may transfer the substrate 122 from the planarizing module 106 to the input module 124 while rotating the substrate to a vertical orientation. The substrate handler 166 then retrieves the substrate from the input module 124 transfers the substrate through the cleaning modules 160 of the cleaning system 116. Each of the modules 160 is adapted to support a substrate in a vertical orientation throughout the cleaning process. Once cleaned, the cleaned substrate 122 is transferred to the output module 156. The cleaned substrate 122 is returned to one of the cassettes 118 by the interface robot 120 while returning the cleaned substrate 122 to a horizontal orientation. Optionally, the interface robot 120 may transfer the cleaned substrate to the metrology system 180 prior to the substrate's return to the cassette 118.

Although any suitable substrate handler may be utilized, the substrate handler 166 depicted in FIG. 1 includes a robot 168 having at least one gripper (two grippers 174, 176 are shown) that is configured to transfer substrates between the input module 124, the cleaning modules 160 and the dryer 162. Optionally, the substrate handler 166 may include a second robot 170 configured to transfer the substrate between the last cleaning module 160 and the dryer 162 to reduce cross contamination.

In the embodiment depicted in FIG. 1, the substrate handler 166 includes a rail 172 coupled to a partition 158 separating the cassettes 118 and interface robot 120 from the cleaning system 116. The robot 168 is configured to move laterally along the rail 172 to facilitate access to the cleaning modules 160, dryer 162 and the input and output modules 124, 156.

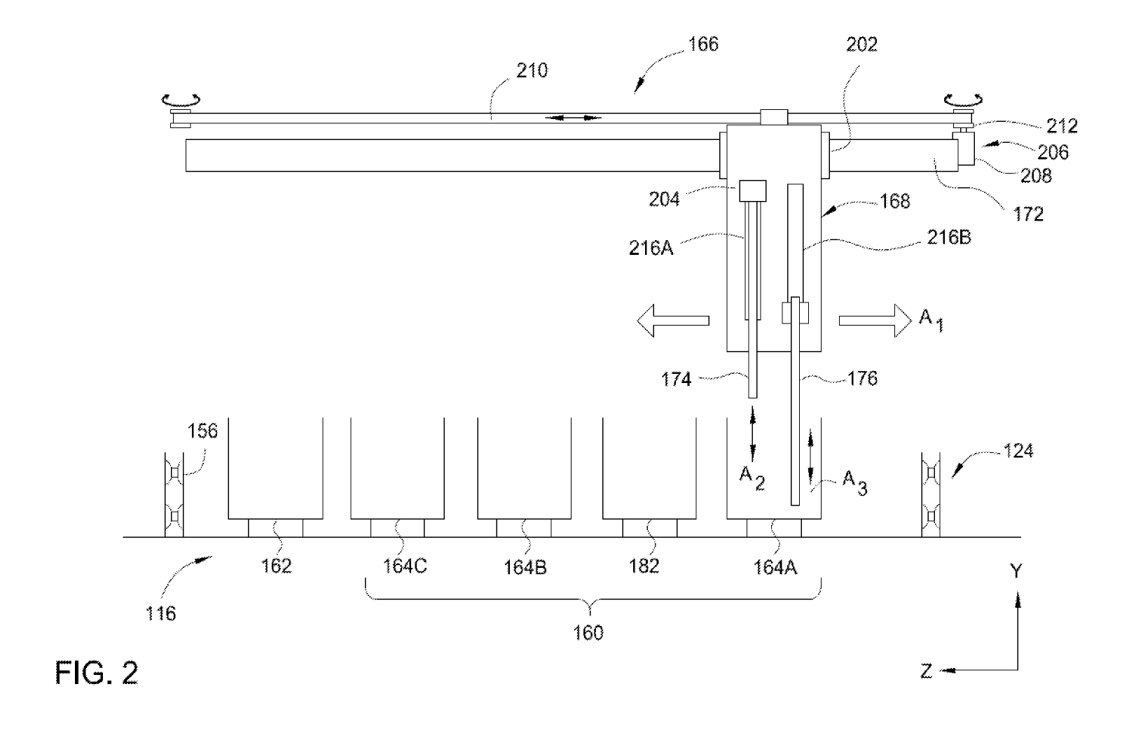

FIG. 2 depicts a front view of the substrate handler 166 according to one embodiment of the invention. The robot 168 of the substrate handler 166 includes a carriage 202, a mounting plate 204 and the substrate grippers 174, 176. The carriage 202 is slideably mounted on the rail 172 and is driven horizontally by an actuator 206 along a first axis of motion A₁ defined by the rail 172 which is parallel to the Z-axis. The actuator 206 includes a motor 208 coupled to a belt 210. The carriage 202 is attached to the belt 210. As the motor 208 advances the belt 210 around the sheave 212 positioned at one end of the cleaning system 116, the carriage 202 moves along the rail 172 to selectively position the robot 168. The motor 208 may include an encoder (not shown) to assist in accurately positioning the robot 168 over the input and output modules 124, 156 and the various cleaning modules 160. Alternatively, the actuator 206 may be any form of a rotary or linear actuator capable of controlling the position of the carriage 202 along the rail 172. In one embodiment, the carriage 202 is driven by a linear actuator having a belt drive, such as the GL15B linear actuator commercially available from THK Co., Ltd. located in Tokyo, Japan.

The mounting plate 204 is coupled to the carriage first 202. The mounting plate 204 includes at least two parallel tracks 216A-B along which the positions of the grippers 174, 176 are independently actuated along a second and third axes of motion A₂, A₃. The second and third axes of motion A₂, A₃ are oriented perpendicular to the first axis A₁ and are parallel to the Y-axis.

FIG. 3 depicts a cross-sectional view of the particle cleaning module 182 of FIG. 1. The particle cleaning module 182 includes a housing 302, a substrate rotation assembly 304, a pad actuation assembly 306 that includes a pad 344, and a pad conditioner 410. The pad 344 may be fabricated from a polymer material. If the particle cleaning module is functioning primarily as a buffing module, then the pad 344 can be a soft polishing pad typically used for buffing. Such as soft polishing pad can be polyurethane and the like, for example, a POLYTEX™ pad available from Rodel, Inc. of Newark, Del. If the particle cleaning module is functioning primarily as a cleaning module rather than a buffing module, then the pad 344 can be a brush pad. Such a brush pad can be rubber, e.g., polyvinyl alcohol (PVA).

The housing 302 includes an opening 308 at a top of the housing and a substrate receiver 310 at a bottom 318 of the housing. A drain 368 is formed through the bottom 318 of the housing 302 to allow fluids to be removed from the housing 302. The opening 308 allows the robot 168 (not shown in FIG. 3) to vertically transfer the substrate to an internal volume 312 defined within the housing 302. The housing 302 may optionally include a lid 330 that can open and close to allow the robot 168 in and out of the housing 302.

The substrate receiver 310 has a substrate receiving slot 332 facing upwards parallel to the Y-axis. The receiving slot 332 is sized to accept the perimeter of the substrate 122, thereby allowing the one of the grippers 174, 176 of the substrate handler 166 to place the substrate 122 in the receiving slot 322 in a substantially vertical orientation. The substrate receiver 310 is coupled to an Z-Y actuator 311. The Z-Y actuator 311 may be actuated to move the substrate receiver 310 upwards in the Y-axis to align a centerline of the substrate 122 disposed in the substrate receiver 310 with a centerline of the substrate rotation assembly 304. Once the centerline of the substrate 122 is aligned with the centerline of the substrate rotation assembly 304, the Z-Y actuator 311 may be actuated to move the substrate receiver 310 in the Z-axis to contact the substrate 122 against the substrate rotation assembly 304, which then actuates to chuck the substrate 122 to the substrate rotation assembly 304. After the substrate 122 has been chucked to the substrate rotation assembly 304, the Z-Y actuator 311 may be actuated to move the substrate receiver 310 in the Y-axis clear of the substrate 122 and the substrate rotation assembly 304 so that the substrate 122 held by the substrate rotation assembly 304 may be rotated without contacting the substrate receiver 310.

The substrate rotation assembly 304 is disposed in the housing 302 and includes a substrate holder 314 coupled to a substrate rotation mechanism 316. The substrate holder 314 may be an electrostatic chuck, a vacuum chuck, a mechanical gripper or any other suitable mechanism for securely holding the substrate 122 while the substrate is rotated during processing within the particle cleaning module 182. The substrate holder 314 can include a pad conditioner 410, which will be described further below.

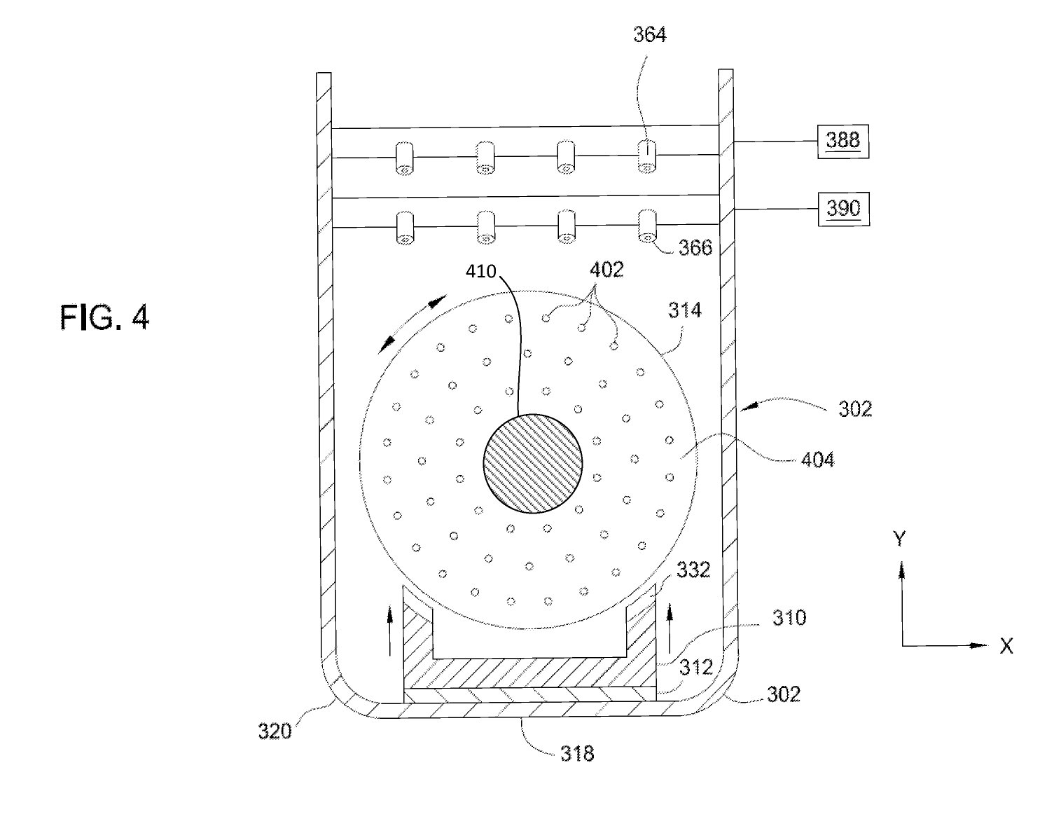

FIG. 4 is a cross-sectional view of the particle cleaning module 182 taken along the section line 4-4 of FIG. 3 thus illustrating a face 404 of the substrate holder 314. Referring to both FIG. 3 and FIG. 4, the face 404 of the substrate holder 314 includes one or more apertures 402 fluidly coupled to a vacuum source 380. The vacuum source 380 is operable to apply a vacuum between the substrate 122 and the substrate holder 314, thereby securing the substrate 122 and the substrate holder 314. Once the substrate 122 is held by the substrate holder 314, the substrate receiver 310 moves downward in a vertical direction parallel to the Y-axis towards the bottom 318 of the housing 318 to be clear of the substrate, as seen in FIG. 4. The substrate receiver 310 may move in a horizontal direction towards an edge of the housing 302 to be further clear of the substrate.

The substrate holder 314 is coupled to the substrate rotation mechanism 316 by a first shaft 323 that extends through a hole 324 formed through the housing 302. The hole 324 may optionally include sealing members 326 to provide a seal between the first shaft 323 and the housing 302. The substrate holder 314 is controllably rotated by the substrate rotation mechanism 316. The substrate rotation mechanism 316 may be an electrical motor, an air motor, or any other motor suitable for rotating the substrate holder 314 and substrate 122 chucked thereto. The substrate rotation mechanism 316 is coupled to the controller 108. In operation, the substrate rotation mechanism 316 rotates the first shaft 323, which rotates the substrate holder 314 and the substrate 122 secured thereto. In one embodiment the substrate rotation mechanism 316 rotates the substrate holder 314 (and substrate 122) at a rate of at least 500 revolutions per minute (rpm).

The pad actuation assembly 306 includes a pad rotation mechanism 336, a pad cleaning head 338, and a lateral actuator mechanism 342. The pad cleaning head 338 is located in the internal volume 312 of the housing 302 and includes a pad holder 334 that holds a pad 344 and a fluid delivery nozzle 350. The fluid delivery nozzle 350 is coupled to a fluid delivery source 382 that provides deionized water, a chemical solution or any other suitable fluid to the pad 344 during cleaning the substrate 122. The lid 330 may be moved to a position that closes the opening 308 of the housing 302 above the fluid delivery nozzle 350 to prevent fluids from being spun out of the housing 302 during processing.

A centerline of the pad holder 334 may be aligned with the centerline of the substrate holder 314. The pad holder 334 (and pad 344) has a diameter much less than that of the substrate 122, for example at least less than half the diameter of the substrate or even as much as less than about one eighth the diameter of the substrate. In one embodiment, the pad holder 334 (and pad 344) may has a diameter of less than about 25 mm. The pad holder 334 may holds the pad 344 utilizing clamps, vacuum, adhesive or other suitable technique that allows for the pad 344 to periodically be replaced as the pad 344 becomes worn after cleaning a number of substrates 122.

The pad holder 334 is coupled to the pad rotation mechanism 336 by a second shaft 346. The second shaft 346 is oriented parallel to the Z-axis and extends from the internal volume 312 through an elongated slit formed through the housing 302 to the pad rotation mechanism 336. The pad rotation mechanism 336 may be an electrical motor, an air motor, or any other suitable motor for rotating the pad holder 334 and pad 344 against the substrate. The pad rotation mechanism 336 is coupled to the controller 108. In one embodiment, the pad rotation mechanism 336 rotates the pad holder 334 (and pad 344) at a rate of at least about 1000 rpm.

The pad rotation mechanism 336 is coupled to bracket 354 by an axial actuator 340 carriage. The axial actuator 340 is coupled to the controller 108 or other suitable controller, and is operable to move the pad holder 334 along the Z-axis to move the pad 344 against and clear of the substrate 122 held by the substrate holder 314. The axial actuator 340 may be a pancake cylinder, linear actuator or any other suitable mechanism for moving the pad holder 334 in a direction parallel to the Z-axis. In operation, after the substrate holder 314 is in contact with and holding the substrate, the axial actuator 340 drives the pad holder 334 in a z-direction to make contact with the substrate.

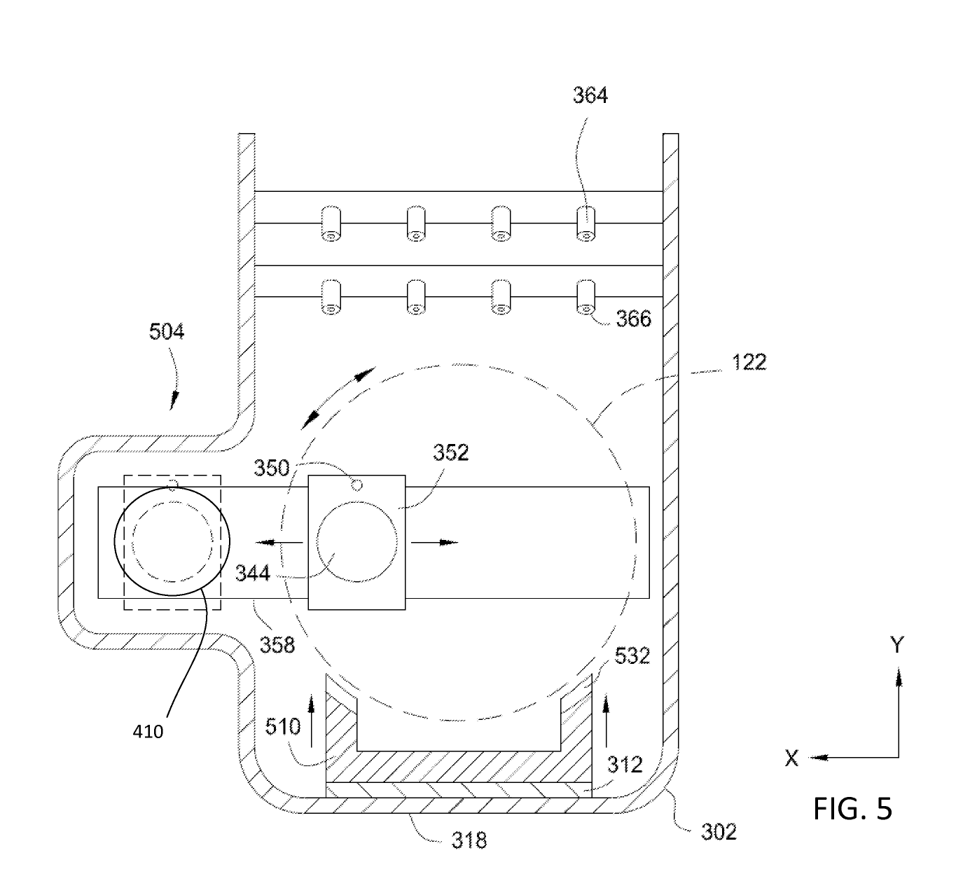

The bracket 354 is coupled to a base 370 by the lateral actuator mechanism 342 by a carriage 352 and rail 358 that allows the pad cleaning head 338 to move laterally in a direction parallel to the X-axis, as depicted in FIG. 5. The carriage 352 is slideably mounted on the rail 358 and is driven horizontally by the lateral actuator mechanism 342 to scan the pad 344 across the substrate 122. The lateral actuator mechanism 342 may be a lead screw, a linear actuator or any other suitable mechanism for moving the cleaning head 338 horizontally. The lateral actuator mechanism 342 is coupled to controller 108 or other suitable controller.

Scanning the polymer pad 344 across the substrate 122 in the particle cleaning module 182 has effectively demonstrated the ability to effectively remove particles, such as abrasives from the polishing fluid, from the surface of the substrate 122. Accordingly, the need for a dedicated buffing station on the polishing module is substantially eliminated.

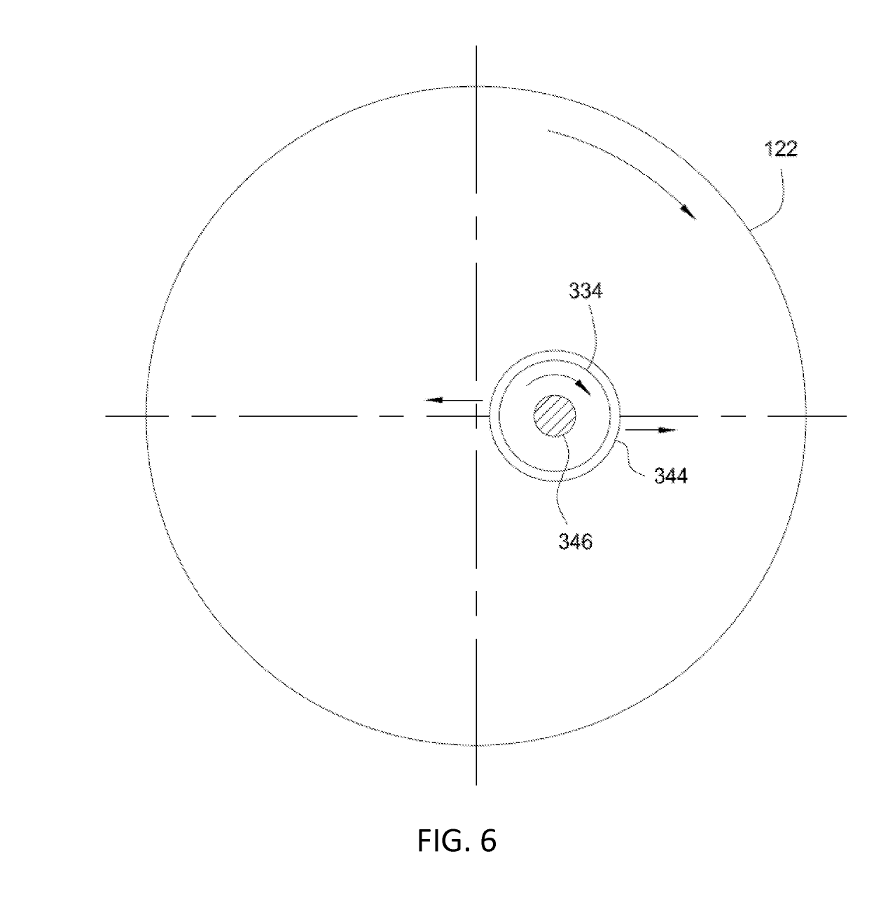

FIG. 6 is a side view of the pad holder 334 engaging the pad 344 with the substrate 122 retained by the substrate holder 314. In operation, the axial actuator 340 urges the pad 344 against the substrate 122 rotated by the substrate rotation mechanism 316 while the pad rotation mechanism 336 spins the pad 344. The lateral actuator mechanism 342 moves the pad holder 334 and pad 344 in a horizontal direction across the surface of the substrate 122. While the pad 344 is in contact with the substrate 122, the fluid delivery nozzle 350 provides at least one of deionized water, a chemical solution or any other suitable fluid to the surface of the substrate 122 being processed by the pad 344. Accordingly, the pad 344 cleans the entire surface of the substrate with minimal movement. One advantage of the invention is the relatively small size of the pad 344 compared to the size of the substrate 122. Conventional systems use large pads positioned on the polishing module to clean smaller substrates, where the substrate is in 100 percent contact with the pad. Large pads are prone to trapping abrasives and particulates which often cause scratches and defects in the substrate. However, the smaller pad of the present invention is significantly less prone to abrasive and particulate trapping, which advantageously results in a cleaner pad and substrates with less scratches and defects. Additionally, the smaller pad of the present invention significantly reduces the cost of consumables, both in the amount of fluid utilized during processing and the cost of replacement pads. Furthermore, the smaller pad of the present invention significantly allows the pad to be easily removed or replaced.

Referring back to FIG. 5, once the substrate is cleaned the pad actuation assembly 306 retracts the pad holder 334 and pad 344 away from the substrate 122 (shown in phantom) and moves the pad holder 334 and pad 344 linearly in a direction parallel to the X-axis away from the substrate and out of the internal volume 312 of the housing 302 into a pocket 504 coupled to the housing 302. Positioning the pad holder 334 and pad 344 in the pocket 504 as shown in phantom in FIG. 5 and out of the internal volume 312 of the housing 302 advantageously provides more space for the robot 168 to enter the housing 302 and transfer the substrate without risk of damaging either the pad 344 or the substrate 122, while allowing the housing 302 to be smaller and less expensive.

Substrate transfer begins after cleaning and moving the pad holder 334 and pad 344 in the pocket 504 by having the substrate receiver 310 move upward in a direction parallel to the Y-axis to engage the substrate 122 in the receiving slot 332. Once the substrate is disposed in the substrate receiving slot 332, the substrate holder 314 releases the substrate 122 by turning off the vacuum provided by the vacuum source 380, and optionally providing a gas through the apertures 402 of the substrate holder 314 to separate the substrate from the substrate holder 314. The substrate receiver 310 with the substrate 122 disposed in the receiving slot 332 is then moved laterally away from the substrate holder 314 in a direction parallel to the Z-axis to clear the substrate 122 from the substrate holder 314. One of the grippers 174, 176 of the robot 168 retrieves the substrate 122 from the substrate receiver 310 and removes the substrate 122 from the housing 302. An optional top spray bar 364 and bottom spray bar 366 are positioned across the internal volume 312 may spray the substrate 122 with deionized water or any other suitable fluid to clean the substrate 122 as the substrate 122 is removed from the particle cleaning module 182 by the robot 168. At least one of the spray bars 364, 366 may be utilized to wet the substrate 122 prior to chucking against the substrate receiver 310 to remove particles that may potentially scratch the backside of the substrate and/or to improve chucking by the substrate receiver 310. The spray bars 364, 366 may be coupled to different fluid sources 388, 390 so that different fluids may be provided to each of the spray bars 364, 366, or both spray bars 364, 366 may be coupled to a single fluid delivery source.

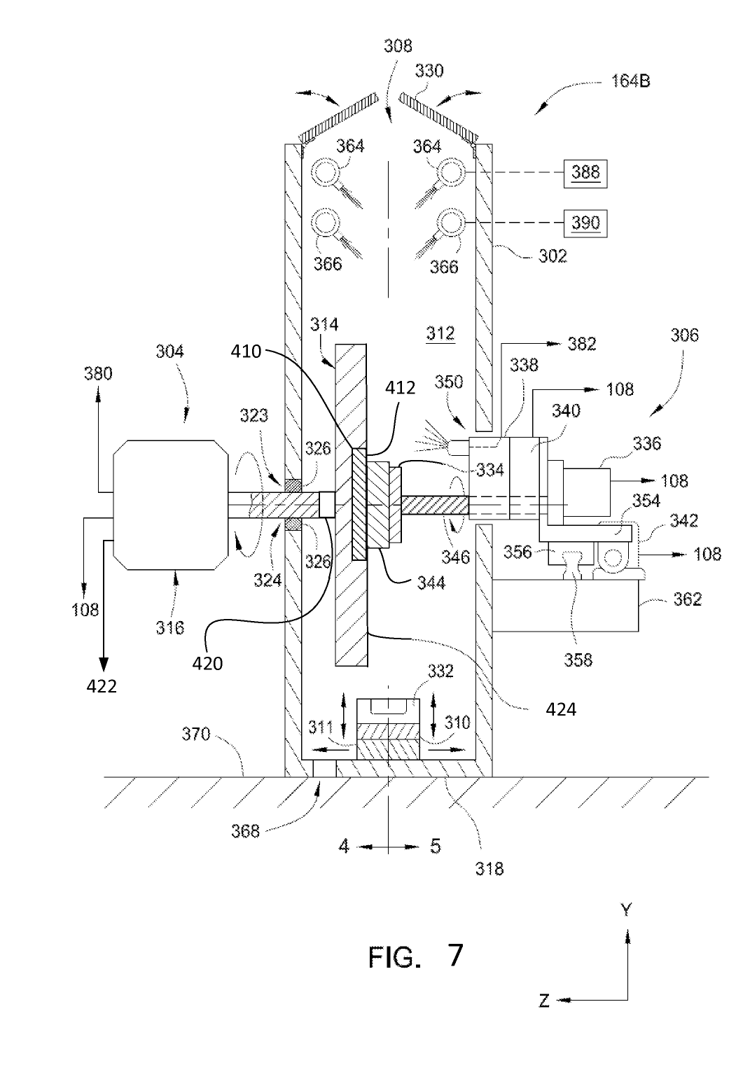

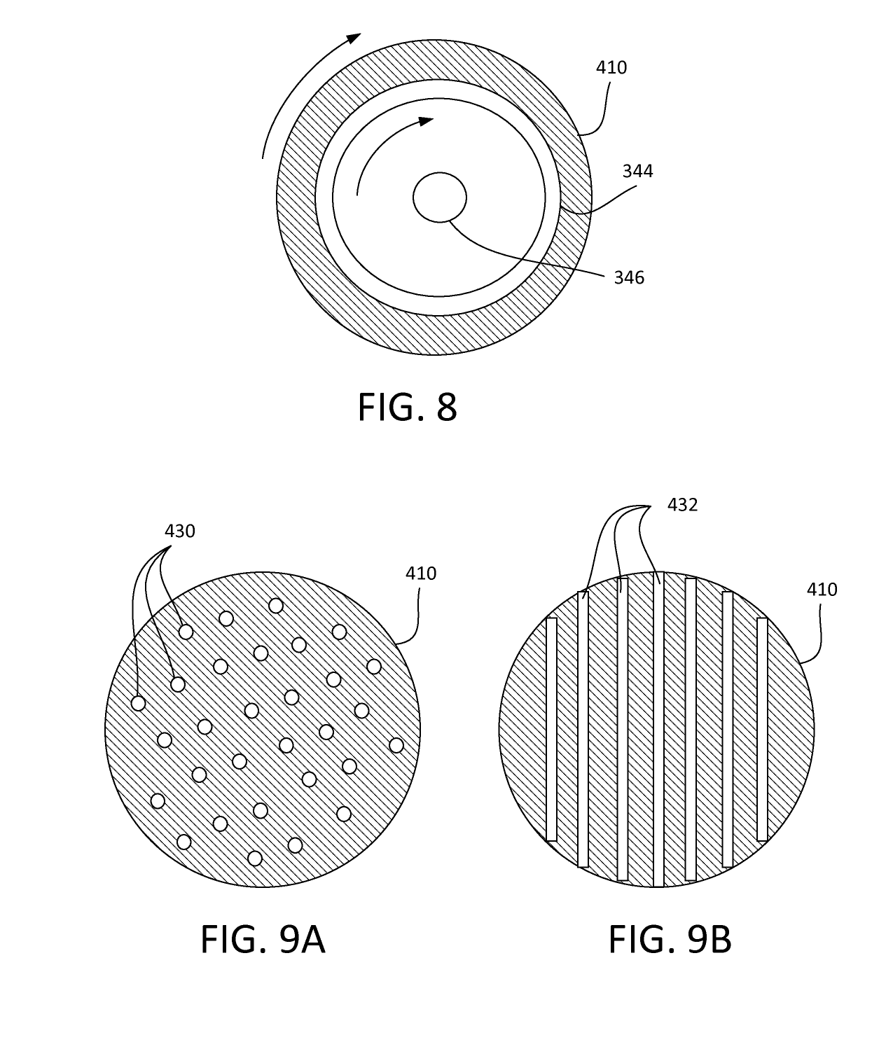

Referring to FIGS. 7 and 8, the particle cleaning module 182 includes a pad conditioner 410. The pad conditioner 410 can be a disk formed of a material that is more rigid than the pad 344. For example, if the pad 344 is a brush pad, e.g., PVA, then the pad conditioner 410 can be glass. As another example, if the pad 344 is a buffing pad, e.g., a polyurethane pad, then the pad conditioner 410 can be a body coated with abrasive diamond grit.

In the implementation illustrated in FIGS. 7 and 8, the pad conditioner 410 is attached to the substrate holder 314. The pad conditioner 410 is oriented vertically, with an outer surface 412 facing toward the pad 344. The outer surface 412 of the pad conditioner 410 is parallel to the face 424 of the substrate holder 314 that contacts the substrate. The pad conditioner 410 can be inset into a recess in the face 424 of the substrate holder 314. Optionally, the outer surface 412 can be slightly recessed relative to the face 424 so that the abrasive outer surface 412 does not contact the substrate 122 when the substrate is held by the substrate holder 314. This can prevent damage or contamination of the substrate 122. The pad conditioner 410 can be located at the center of the substrate holder 314, e.g., the axis of rotation of the pad holder 314 can pass through the approximate center of the pad conditioner 410.

Pad conditioning can begin once the substrate 122 no longer blocks access of the pad 344 to the pad conditioner 410, e.g., after the substrate 122 is removed from the particle cleaning module 182. In operation, the axial actuator 340 urges the pad 344 against the pad conditioner 410. Relative motion between the pad 344 and the conditioner 410 is generated, e.g., by rotating the pad conditioner 410 with the substrate rotation mechanism 316 and/or rotating the pad 344 with the pad rotation mechanism 336. If the pad conditioner is large enough, then optionally the lateral actuator mechanism 342 moves the pad holder 334 and pad 344 in an oscillating horizontal motion across the surface of the conditioner 410. While the pad 344 is in contact with the substrate 122, the fluid delivery nozzle 350 can provide a cleaning liquid, e.g., at least one of deionized water, a chemical solution or another suitable fluid to the interface between the pad conditioner 410 and the pad 344.

Although FIGS. 7 and 8 illustrate the pad conditioner 410 attached to the substrate holder 314, other locations are possible for the pad conditioner. For example, as shown in FIG. 5, the pad conditioner 410 can instead be located to the side of the substrate holder 314, e.g., in the pocket 504 of the housing 302. An additional conditioner rotation mechanism could be included to provide rotation of the pad conditioner 410. The conditioner rotation mechanism can be constructed in a manner similar to the substrate rotation mechanism, with a drive shaft passing through the wall of the particle cleaning module 182 to a motor.

Referring to FIG. 8, in some implementations, both the pad conditioner 410 and the pad 344 rotate. For example, for a conditioning operation, the pad conditioner 410 can rotate at about 200-2000 rpm, e.g., about 1000 rpm, and the pad 344 can also rotate at about 200-2000 rpm, e.g., 800 rpm. The pad 344 and pad conditioner 410 can be rotated in the same direction at different speeds, or in opposite directions. The pad 344 can be pressed against the pad conditioner with a pressure of about 0.5-2 psi, e.g., 1 psi.

An advantage of placing the pad conditioner 410 on the substrate holder 314 is the conditioner does not occupy extra space and that extra mechanical components to provide rotation of the pad conditioner 410 are not needed. An advantage of placing the pad conditioner in the pocket 504 is that the pad 344 can be conditioned while the substrate 122 is positioned on the substrate holder 314.

Referring to FIG. 9A, in some implementations, the pad conditioner 410 can include a plurality of passages 430 that exit on the outer surface 412. While the pad 344 is in contact with the substrate 122, a cleaning liquid, e.g., at least one of deionized water, a chemical solution or another suitable fluid, can be delivered through the passages 430 to the interface between the pad conditioner 410 and the pad 344.

Referring to FIG. 9B, in some implementations, which can optionally be combined with the passage of FIG. 9A, a plurality of grooves 432 are formed on the outer surface of the pad conditioner 432. The grooves 432 can carry away debris dislodged from the pad 344. Although illustrated as parallel grooves in FIG. 9B, the grooves can be extend radially outward from the center of the pad conditioner 410, or be concentric circles, or be some other pattern or combination of patterns.

Returning to FIG. 7, the particle cleaning module 182 can also include a pressure sensor 430. The pressure sensor can includes a vertical contact surface. The module 182 is configured such that the axial actuator 340 can move the pad 344 into contact with the contact surface, and the pressure sensor 430 is configured to generate a signal representing an applied pressure of the pad 344 pressed against the contact surface. The signal can be sent to the controller 108 on a data line 432.

In some implementations, the pressure sensor 430 measures the pressure of the pad 344 against the pad conditioner 410. That is, the contact surface can be the outer surface 412 of the pad conditioner 410. The pressure sensor can be a load cell, and can be positioned between the pad conditioner and a rigid component of the pad rotation mechanism 336. For example, in the implementation shown in FIG. 7, the load cell 430 can be positioned between the substrate holder 314 and the draft shaft that extends from the substrate rotation mechanism 316. However, in other implementations, the load cell 430 could be positioned between the pad conditioner 410 and the substrate holder 314, or between two axially separated portions of the drive shaft.

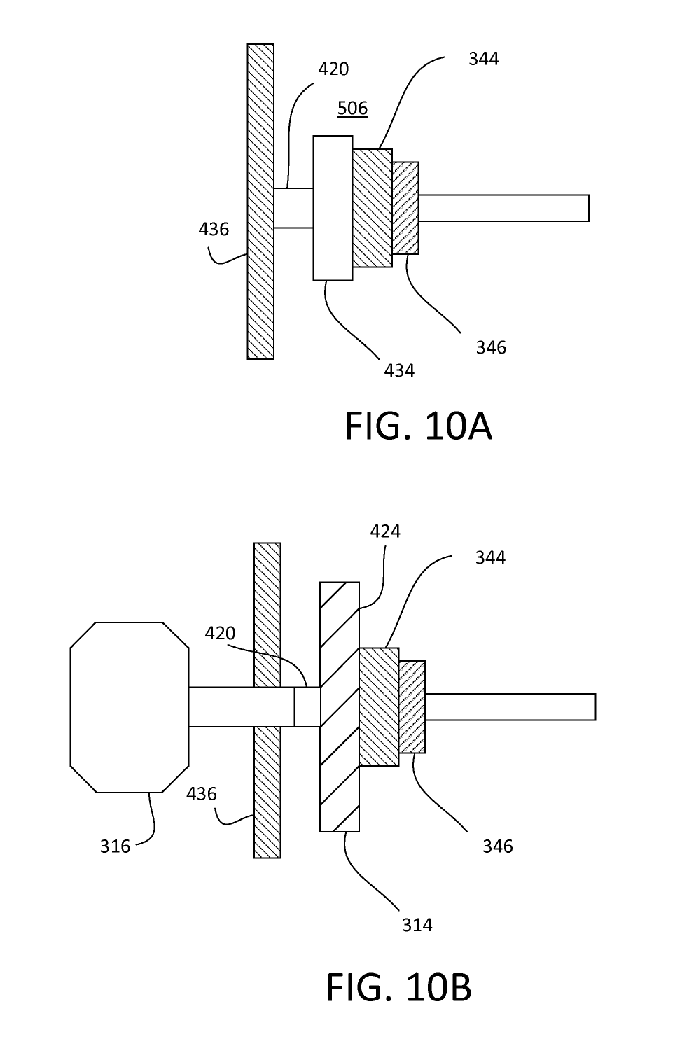

In some implementations, the pressure sensor 430 measures the pressure of the pad 344 against a surface other than the pad conditioner. For example, if the pad conditioner 410 is positioned on the substrate support 314, then as shown in FIG. 10A, the contact surface could be the surface of a body 434 located in the pocket 504. In this case, the load cell 430 can be located between the body 434 and another rigid part, e.g., the wall 436 of the particle cleaning module 186. Conversely, if the pad conditioner 410 is located in the pocket, the contact surface could be the surface 424 of the substrate holder 314. In this case, as shown in FIG. 10B, the load cell 430 can be positioned between the substrate holder 314 and the draft shaft that extends from the substrate rotation mechanism 316 or between two axially separated portions of the drive shaft.

Either the axial actuator 340 or a controller that controls the axial actuator 340, e.g., controller 108, is configured to generate a signal representing the horizontal position of the pad holder 334. For example, the axial actuator can include a linear encoder that measures linear translation of a component of the pad actuation assembly 306, e.g., the second shaft 346. The linear encoder can send the signal to the controller 108. Alternatively or in addition, the controller 108 could monitor a voltage level used to control the axial actuator 340.

As noted above, the pad 344 wears over time. If the pad actuation assembly were to position the pad holder 346 at the same axial position for each substrate, then the compression of the pad 344 against the substrate would vary from substrate-to-substrate, resulting in variations in effectiveness of cleaning or buffing from substrate-to-substrate. However, by using a pressure sensor 430 to measure the pressure applied by the pad 344 as a function of the axial position of the pad holder, a controller can adjust the axial position of the pad support to improve consistency of compression from substrate-to-substrate.

In operation, at some time a “fresh” pad 344, e.g., a pad that has not be used for buffing or cleaning yet, is installed on the pad support 346. The pad actuator assembly 306 moves the pad holder 334 to a position Z1 at which the pad 344 abuts the contact surface of the pressure sensor. The load on the load cell 430 is measured for the pad holder at the position Z1. The position Z1 could be a preset position, or the axial actuator 340 could advance the pad holder 344 horizontally until the load on the load cell 430 reaches a preset load value. Assuming that the load cell 430 is integrated with the substrate holder 314, the pad 344 is moved along the Z-axis away from the substrate holder 314 so that a substrate can be lowered into the particle cleaning module 186 as described above.

One or more substrates are processed in the particle cleaning module 186. To perform this processing, the axial actuator 340 advances the pad holder to a position Z2 in which the pad 344 contacts the substrate 10.

After cleaning or buffing of one or more substrates in the particle cleaning module 186, the pad actuator assembly 306 returns the pad 344 into contact with the contact surface of the pressure sensor 430. In some implementations, the axial actuator 340 advances the pad holder 334 horizontally along the Z-axis until the load cell 430 reaches the same preset load value. The position Z3 of the pad holder which generates this load value is determined from the signal representing the horizontal position of the pad holder 334. The controller can determine a difference ΔZ from Z3-Z1.

For processing of a subsequent substrate 10, when the pad 334 is returned into contact with a substrate 10, the axial actuator 340 advances the pad holder 334 by an additional amount based on the difference, e.g., to a position Z4=Z3+ΔZ. Consequently, even though the pad wears, the pressure applied by the pad 344 during processing should be more consistent from substrate-to-substrate, thereby improving substrate-to-substrate uniformity.

The controller 108 can receive the signal representing the pressure of the pad 344 against the contact surface, can receive the signal representing the horizontal position of the pad holder 334, can store and/or calculate the preset pressure value and the position values Z1, Z2, Z3, Z4.

Referring back to the planarizing module 106 of FIG. 1, both of the second and third station 130, 132 may be used to perform CMP process as the particle cleaning module 182 substantially eliminates the need for a buffing pad disposed in one of the stations 130, 132 as required in conventional systems. Since the second and third station, 130, 132 to be used for CMP processes, the use of the particle cleaning module 182 advantageously increases the throughput of the CMP system 100. The vertical substrate orientation of the particle cleaning module 182 is also beneficial, as it removes particles in a more compact footprint as compared to traditional horizontal designs utilized on the polishing module.

Furthermore, the particle cleaning module 182 effectively cleans the substrate and decreases the loading of particulate on the brushes of the first brush module 164B and second brush module 164C. Therefore, the lifespan of the brushes in the first brush module 164B and second brush module 164C are advantageously increased. Thus, the particle cleaning module removes particularly difficult to remove polishing fluids without requiring a buffing station in the polishing module and simultaneously frees the second and or third station for additional CMP stations to increase throughput of the planarizing system.

It is contemplated that the CMP station may be configured as an electrochemical mechanical planarizing station.

While the foregoing is directed to some embodiments, other and further embodiments of the invention may be devised without departing from the scope of the claims.

What is claimed is:

1. A particle cleaning module, comprising:
a housing;
a substrate holder disposed in the housing, the substrate holder configured to retain a substrate in a substantially vertical orientation, the substrate holder rotatable on a first axis;
a pad holder disposed in the housing, the pad holder having a pad retaining surface facing the substrate holder in a parallel and spaced apart relation, the pad holder rotatable on a second axis parallel to the first axis;
an actuator operable to move the pad holder relative to the substrate holder to change a distance defined between the pad retaining surface and the substrate; and
a pad conditioner disposed in the housing, the pad conditioner having a conditioning surface, the conditioning surface oriented parallel to the pad retaining surface.

2. The module of claim 1, wherein the substrate holder is configured to hold the substrate in a plane, and the conditioning surface is positioned on a side of the plane further from the pad holder.

3. The module of claim 1, wherein the pad conditioner is mounted on and rotates with the substrate holder.

4. The module of claim 3, wherein the first axis of rotation passes approximately through a center of the pad conditioner.

5. The module of claim 3, wherein the conditioning surface is recessed relative to a substrate mounting surface of the substrate holder.

6. The method of claim 1, wherein the actuator is operable to move the pad support along a direction parallel to the second axis.

7. The module of claim 6, wherein the actuator is operable to move the pad support laterally along a direction perpendicular to the second axis to a position laterally separated from the substrate holder, and the pad conditioner is located at the position laterally separated from the substrate holder.

8. The module of claim 1, further comprising the pad, and wherein the pad is polyurethane and the pad conditioner comprises abrasive diamond particles.

9. The module of claim 1, further comprising the pad, and wherein the pad is a polyvinyl alcohol and the pad conditioner comprises glass.

10. The module of claim 1, further comprising passages through the pad conditioner and a cleaning liquid supply to inject the cleaning liquid through the passages.

11. A particle cleaning module, comprising:
a housing;
a substrate holder disposed in the housing, the substrate holder configured to retain a substrate in a substantially vertical orientation in a first plane;
a pad holder disposed in the housing, the pad holder having a pad retaining surface and configured to retain a pad in a substantially vertical orientation in a second plane parallel to the first plane;
an actuator operable to move the pad holder relative to the substrate holder along a direction normal to the first plane to change a distance between the first plane and the second plane, the actuator configured to generate or receive a first signal representing a horizontal position of the substrate holder along the direction;
a pad conditioner disposed in the housing, the pad conditioner having a conditioning surface, the conditioning surface oriented parallel to the pad retaining surface; and
a pressure sensor having a contact surface and configured to generate a second signal representing a load on the contact surface.

12. The module of claim 11, further comprising a controller configured to receive the first signal and the second signal.

13. The module of claim 12, wherein the controller is configured to cause the actuator to adjust a horizontal position of the substrate holder based on the first signal and the second signal.

14. The module of claim 12, wherein the controller is configured to measure a position Z1 of the substrate holder for a pressure P1 prior to processing of a first substrate, and is configured to determine a position Z3 of the substrate holder to achieve the pressure P1 after processing of the first substrate.

15. The module of claim 14, wherein the controller is configured to position the substrate holder at a position Z2 during processing of the first substrate, and is configured to position the substrate holder at a position Z4=Z2+ΔZ for polishing of a subsequent second substrate, where ΔZ=Z3−Z1.

16. The module of claim 11, wherein the contact surface comprises the conditioning surface.

17. The module of claim 16, wherein the pad conditioner is mounted on the substrate holder.

18. The module of claim 17, wherein the pressure sensor comprises a load cell positioned between the pad conditioner and a motor to rotate a drive shaft secured to the substrate holder.

19. The module of claim 11, wherein contact surface comprises the pad retaining surface.

20. The module of claim 11, wherein the substrate holder is rotatable about a first axis and the pad holder is rotatable about a second axis parallel to the first axis.
